(19) United States
(12) Patent Application Publication
(10) Pub. No.: US 2004/0112424 A1
(43) Pub. Date: Jun. 17, 2004

(54) Solar cell assembly, and photovoltaic solar electric generator of concentrator type

(75) Inventors: Kenji Araki, Nagoya-shi (JP); Michio Kondo, Nagoya-shi (JP); Hisafumi Uozumi, Nagoya-shi (JP)

Correspondence Address: OLIFF & BERRIDGE, PLC, P.O. BOX 19928, ALEXANDRIA, VA, 22320, US

(73) Assignee: DAIDO STEEL CO., LTD., Nagoya-shi (JP)

(21) Appl. No.: 10/671,444

(22) Filed: Sep. 29, 2003

(30) Foreign Application Priority Data
Nov. 19, 2002 (JP) 2002-334691
Oct. 3, 2002 (JP) 2002-290728

(51) Int. Cl. H01L 31/00

(52) U.S. Cl. 136/256; 136/246; 136/259

(57) ABSTRACT

A solar cell assembly including a solar cell, a first lead electrode bonded to an end portion of one of opposite surfaces of the solar cell which functions as a light-receiving surface, a second lead electrode bonded to a substantially entire portion of the other of the opposite surfaces of the cell, and a metallic sheet which is bonded to one of opposite surfaces of the second lead electrode remote from the solar cell, and which has a lower coefficient of thermal expansion than the second lead electrode. Also disclosed is a photovoltaic electric generator of concentrator type including an array of a plurality of solar cell assemblies, and electrically conductive members in the form of metallic foils connected to the solar cell of each assembly, a heat dissipating layer formed of a synthetic resin containing a thermally conductive filler, and a base plate to which each cell assembly is fixed through the heat dissipating layer. The solar cell assembly is embedded in the heat dissipating layer.

This application is based on Japanese Patent Application No. 2002-290728 filed Oct. 3, 2002 and 2002-334691 filed Nov. 19, 2002, the contents of which are incorporated hereinto by reference.

### BACKGROUND OF THE INVENTION

1. Field of the Invention

The present invention relates to an improvement of an electrode structure of a solar cell assembly, which is free from cracking at a junction of lead electrodes, and an improvement of a photovoltaic electric generator of concentrator type including solar cells arranged to convert a concentrated solar radiation energy into an electric energy.

2. Discussion of Related Art

There is known a photovoltaic power generator of concentrator type including an array of solar cells which are fixed to a base plate provided in a casing that accommodates a primary optical system including non-imaging Fresnel lenses arranged to receive incident solar radiation. The solar cells are electrically connected in series with each other through an elongate metallic foil (electrically conductive member) fixed at its opposite end portions to and between a lower electrode formed on a lower surface of one of the two adjacent solar cells and upper electrodes formed on an upper surface of the other solar cell. In this concentrator photovoltaic electric generator, the solar radiation concentrated by the primary optical system is received by the light-receiving surfaces of the solar cells, which convert the solar radiation energy into an electric energy, whereby electric power is generated from the solar radiation.

The solar cells used in such a photovoltaic electric generator of concentrator type provide an output of a relatively low voltage of 2.5V and a relatively large amount of current of 2.5 A, for example. To reduce the electric resistance of the electrodes, lead electrodes (electrically conductive members) for supplying an electric current are required to be formed from copper sheets having a thickness of not smaller than 0.1 mm, for instance.

Referring to FIG. 5, there is shown a solar cell 1 to which two upper lead electrodes 2A and 2B and one lower lead electrode 3 are connected, such that an upper surface of the solar cell 1 is connected only at its opposite end portions to the respective two upper lead electrodes 2A, 2B so that the solar radiation is incident upon a relatively large area of the upper surface (light-receiving surface), while the lower surface of the solar cell 1 is connected over its entire area to the lower lead electrode 3, for minimizing the electric and thermal resistances. As also shown in FIG. 5, the upper surface of the solar cell 1 is provided with a multiplicity of parallel stripe electrodes 8 which extend between the above-indicated opposite end portions. These stripe electrodes 8 are electrically connected to upper electrodes in the form of two bus-bar electrodes 9 formed along the respective edges of the above-indicated opposite end portions of the upper surface of the solar cell 1, as shown in FIG. 6, such that the bus-bar electrodes 9 each having a suitable width extend in a direction perpendicular to the direction of extension of the stripe electrodes 8. The upper lead electrodes 2A and 2B are connected to these bus-bar electrodes 9. “Electrical Engineers' College Study Course entitled “Fundamentals of Power Electronics”, p48, edited by Institute of Electrical Engineers and published on Apr. 20, 1993, discloses the use of a thin layer of tungsten between a Si diode element and a Cu stud, for the purpose of eliminating a strain due to a difference between coefficients of thermal expansion of the Si diode element and the Cu stud.

The coefficient of thermal expansion of the copper sheet used for the lead electrodes 2A, 2B is more than about ten times as high as that of the solar cell 1 formed of Ge, for example. Accordingly, the solar cell 1 is deformed into an almost part-spherical shape, with its opposite major surfaces being convexed upwardly or in a direction from the lower surface toward the upper surface, as shown in FIG. 6, in the process of a temperature drop of the solar cell 1 to the ambient temperature after the lower lead electrode 3 is soldered to the solar cell 1 at a temperature of 250-260° C. On the other hand, the solar cell 1 is deformed into an almost part-cylindrical shape, with its opposite major surfaces being convexed downwardly or in a direction from the upper surface toward the lower surface, as shown in FIG. 7, in the process of a temperature drop of the solar cell 1 after the upper lead electrodes 2A, 2B are soldered to the opposite end portions of the upper surface of the solar cell 1. As a result, the connection of the upper lead electrodes 2A, 2B and the lower lead electrode 3 to the solar cell 1 gives rise to a risk of generation of undesirable cracking of the solar cell 1 due to an excessively large shear stress at or near the junctions to the upper lead electrodes 2A, 2B, as indicated by broken lines in FIG. 8A.

To fix the solar cells to the base plate provided in the casing of a photovoltaic electric generator, there has been proposed a technique to bond the solar cells onto the base plate with a pressure sensitive adhesive under a suitable pressure, as disclosed in U.S. Pat. No. 5,498,297. However, such a pressure sensitive adhesive when it is used to fix the solar cells to the base plate suffers from a low degree of stability after heat treatment of the photovoltaic electric generator, in particular, insufficient degrees of reliability and resistance to the solar radiation, in highly humid and/or highly dewy places of use of the photovoltaic electric generator, such as Japan. It is further noted that the photovoltaic electric generator of concentrator type is generally exposed to a severe heat cycle, that is, alternately exposed to heat generated by the concentrated solar radiation in the daytime, and cooling down to the ambient temperature in the night, so that the photovoltaic electric generator may suffer from removal of the solar cells and deterioration of its electrical insulation, after a long period of use.

In view of the drawbacks of the pressure sensitive adhesive, there has been proposed a technique to fix the solar cells to the base plate with a thermally conductive epoxy resin, as disclosed in “A SIMPLE PASSIVE COOLING STRUCTURE AND ITS HEAT ANALYSIS FOR 500 X CONCENTRATOR PV MODULE”, Kenji Araki et al., 29^{th} IEEE PVSC Conference, 2002 New Orleans, USA. This technique uses a heat dissipating layer which is interposed between a solar cell and a base plate and which is formed of an epoxy resin in which a thermally conductive filler is dispersed. This layer of epoxy resin effectively functions to reduce the temperature difference between the solar cell and the base plate. The epoxy resin used for the dissipating layer is the one that has demonstrated excellent durability and stability in the outdoor use, in the field of outdoor building structures. Namely, the heat dissipating layer of the epoxy resin permits efficient heat dissipation from the solar cell, and enables the photovoltaic electric generator of concentrator type to assure highly efficiency conversion from the solar radiation energy into the electric energy, and high degrees of operating reliability and resistance to the solar radiation.

However, the thermally conductive epoxy resin suffers from reduction of its adhesive force with an increase in the amount of the filler added thereto. Therefore, the solar cell must be bonded to the base plate with a sufficiently large force, in order to provide a sound interface of adhesion between the solar cell and the base plate through the heat dissipating layer, which interface assures a high degree of operating reliability of the photovoltaic electric generator, while maintaining a high degree of thermal conductivity of the dissipating layer. At the same time, the thickness of the solar cell is preferably reduced as much as possible, in order to reduce the internal electric and thermal resistance of the solar cell. Accordingly, the application of a large force to the solar cell for bonding it to the base plate has a high risk of cracking of the solar cell. Further, the width of the electrically conductive members indicated above is preferably increased as much as possible, for reducing the electric resistance and improving the heat dissipation property, so that the conductive strips are subject to a stress concentration upon hardening or curing of the thermally conductive adhesive, resulting in a further increase in the risk of cracking of the solar cell.

### SUMMARY OF THE INVENTION

The present invention was made in view of the background art discussed above. It is a first object of the present invention to provide a solar cell assembly, which is arranged to minimize a risk of cracking of a solar cell upon soldering of lead electrodes to the solar cell. A second object of the invention is to provide a photovoltaic electric generator of concentrator type wherein each of a plurality of solar cells is bonded to a base plate with a sufficiently large force, without cracking or other drawbacks of the solar cells.

The first object indicated above may be achieved according to a first aspect of the present invention, which provides a solar cell assembly comprising:

a solar cell having opposite surfaces one of which functions as a light-receiving surface;

a first lead electrode bonded to an end portion of the above-indicated one of the opposite surfaces of the solar cell;

a second lead electrode bonded to a substantially entire portion of the other of the opposite surfaces; and

a metallic sheet which is bonded to one of opposite surfaces of the second lead electrode which is remote from the solar cell, the metallic sheet having a lower coefficient of thermal expansion than the second lead electrode.

In the solar cell assembly structure constructed according to the first aspect of this invention described above, the metallic sheet bonded to the surface of the second lead electrode which is remote from the solar cell functions to reduce an amount of shrinkage of the second lead electrode which takes place on its side remote from the solar cell in the process of a temperature drop of the solar cell assembly to the ambient temperature after bonding of the second lead electrode to the solar cell. Accordingly, the metallic sheet is effective to reduce the amount of upwardly convex deformation of the solar cell assembly into a part-spherical shape due to the shrinkage. This reduction of the amount of upwardly convex deformation of the solar cell assembly results in significant reduction of a shear stress which is generated at and near the junction between the first lead electrode and the solar cell, due to opposite directions of the upwardly convex deformation and downwardly convex deformation of the solar cell assembly into a part-cylindrical shape which takes place in the process of a temperature drop of the solar cell assembly to the ambient temperature after bonding of the first lead electrode to the solar cell. Thus, the metallic sheet effectively functions to reduce a risk of cracking of the solar cell due to the shear stress in the process of bonding of the lead electrode to the solar cell. The term “a substantially entire portion” of the other of the opposite surfaces of the solar cell described above is interpreted to mean that the surface of the solar cell in question is bonded over a sufficiently large area thereof to the second lead electrode, so as to minimize the electrical and thermal resistances.

Where the solar cell is more or less deformed into a part-spherical shape with its opposite major surfaces being downwardly convexed during the temperature drop after bonding of the second lead electrode to the solar cell, in the presence of the metallic sheet bonded to the second lead electrode, the first lead electrode is deformed in the same downward direction during the temperature drop after bonding of the first lead electrode to the solar cell. In this case, the shear stress at and near the first lead electrode is more effectively reduced, or even eliminated, so that the solar cell is effectively protected against cracking after bonding of the first and second lead electrodes to the respective opposite surfaces of the solar cell.

The amount of deformation of the solar cell after bonding of the first and second lead electrodes to the solar cell is determined by values of the Young's modulus and thermal expansion coefficient of the solar cell, the first and second lead electrodes, the metallic sheet and a solder used for the bonding, and can be obtained by an experimentation. Where the solar cell is formed of Ge while the first and second lead electrodes are copper sheets, the metallic sheet may be formed of a Ni—Fe alloy. Where the solar cell has a thickness of 0.15-0.17 mm while the first and second lead electrodes have a thickness of 0.1 mm, for example, the metallic sheet preferably has a thickness of about 0.3 mm. In this case, the metallic sheet causes the solar cell to have downwardly convex deformation into a part-spherical shape in the process of the temperature drop to the ambient temperature after soldering of the second lead electrode to the solar cell. The material, thickness and other parameters of the metallic sheet may be determined so that the solar cell maintains a planar shape without deformation in the process of the temperature drop after the soldering of the second lead electrode.

In one preferred form of the solar cell assembly, the metallic sheet has a major surface area larger than a surface area of the opposite surfaces of the solar cell, and includes opposite end portions which extend from respective opposite ends of the solar cell in respective opposite directions in which the second lead electrode extends. In this case, portions of the second lead electrode which are located outwardly of the solar cell in the above-indicated opposite directions are also supported by the metallic sheet larger than the solar cell. This arrangement is advantageous where the solar cell assembly including the solar cell and the first and second electrodes is bonded to a heat dissipating plate or base plate via a resin sheet, which is interposed between the metallic sheet and the heat dissipating plate. Namely, when the solar cell assembly is bonded to the heat dissipating plate via the resin sheet, the assembly is forced downwards at the above-indicated portions of the second lead electrode which are located outwardly of the periphery of the solar cell, so that the resin sheet including a central portion located right below the solar cell is compressed to a reduced thickness, via the metallic sheet onto the heat dissipating plate, whereby the resin sheet thus compressed has a reduced thermal resistance, permitting efficient heat dissipation from the solar cell assembly by the heat dissipating plate.

In one advantageous arrangement of the above-indicated preferred form of the solar cell assembly, the metallic sheet is substantially aligned with the solar cell in a plane parallel to the opposite surfaces of the solar cell.

Preferably, the metallic sheet has substantially the same coefficient of thermal expansion as said solar cell. In this instance, the upwardly convex deformation of the solar cell into a part-spherical shape after bonding of the second lead electrode to the solar cell can be further reduced.

Preferably, the solar cell assembly according to the first aspect of this invention is fabricated by a process comprising: (a) a first-lead-electrode bonding step of bonding the first lead electrode to the above-indicated end portion of one of the opposite surfaces of the solar cell that functions as the light-receiving surface, (b) a second-lead-electrode bonding step of bonding the second lead electrode to the above-indicated substantially entire portion of the other of the opposite surfaces of the solar electrode, (c) metallic-sheet bonding step effected during or prior to the above-indicated first-lead-electrode bonding step and second-lead-electrode bonding step, to bond the metallic sheet to one of the opposite surfaces of the second lead electrode which is remote from the solar cell. When the first and second lead electrodes are bonded to the solar cell in the present process, the amount of contraction or shrinkage of the second lead electrode during a temperature drop of the second lead electrode to the ambient temperature is reduced or restricted by the metallic sheet bonded to the surface of the second lead electrode which is remote from the solar cell. Accordingly, the upwardly convex deformation of the solar cell due to a difference between the thermal expansion coefficients of the second lead electrode and the solar cell can be effectively reduced. This arrangement makes it possible to minimize the shear stress due to this upwardly convex deformation of the solar cell and the downwardly convex deformation of the same due to a difference between the thermal expansion coefficients of the first lead electrode and the solar cell. Accordingly, the cracking of the solar cell due to the shear stress is minimized.

The advantage of the process is obtained in the presence of the metallic sheet which functions to reduce the shear stress which acts on the solar cell during or after bonding of the first and second lead electrodes to the solar cell. The expression “during or prior to the above-indicated first-lead-electrode bonding step and second-lead-electrode bonding step” used in connection with the bonding of the metallic sheet to the second lead electrode is interpreted to mean that the metallic sheet is bonded to the second lead electrode concurrently with the bonding of the first and second electrodes to the solar cell, or after the lead electrodes have been bonded to the solar cell. For example, there are the following four alternative cases in connection with the timing of bonding of the metallic sheet with respect to the timings of the first and second lead electrodes:

(1) The metallic sheet is bonded to the second lead electrode concurrently with the bonding of the first and second lead electrodes to the solar cell.

(2) Initially, the first lead electrode is bonded to the solar cell, and the second lead electrode and the metallic sheet are bonded to each other. Then, the second lead electrode to which the metallic sheet has been bonded is bonded to the solar cell to which the first lead electrode has been bonded.

(3) Initially, the second lead electrode and the metallic sheet are bonded to the solar cell. The second lead electrode may be first bonded to the solar cell before the metallic sheet is bonded to the second electrode. Alternatively, the second lead electrode and the metallic sheet are concurrently bonded to the solar cell. Then, the first lead electrode is bonded to the solar cell.

(4) Initially, the second lead electrode is bonded to the solar cell. Then, the metallic sheet and the first electrode are bonded to the second lead electrode and the solar cell, respectively, in this order or concurrently.

Where the metallic sheet has a major surface area larger than a surface area of the opposite surfaces of the solar cell and includes opposite end portions which extend from respective opposite ends of the solar cell in respective opposite directions in which the second lead electrode extends, the above-indicated process may further comprise an epoxy-resin-sheet forming step of forming an epoxy resin sheet on a heat dissipating base plate, and a thermally fixing step of fixing the solar cell assembly consisting of the solar cell, first and second lead electrodes and metallic sheet, to the heat dissipating base plate through the epoxy resin sheet, by first placing the solar cell assembly on the epoxy resin sheet, and forcing the solar cell assembly onto the heat dissipating base plate while heating the epoxy resin sheet. In this case, the solar cell assembly is forced on to the heat dissipating base plate, at portions of the second lead electrode which are located outwardly of and adjacent to the periphery of the solar cell, so that the epoxy resin sheet is compressed and deformed by the metallic sheet located below the second lead electrode, whereby the thickness of the epoxy resin sheet is reduced at a portion thereof corresponding to the metallic sheet. Accordingly, the thermal resistance of the epoxy resin is reduced to assure efficient heat dissipation from the solar cell assembly through the generally thinned epoxy resin sheet and the heat dissipating base plate.

The second object indicated above may be achieved according to a second aspect of this invention, which provides a photovoltaic electric generator of concentrator type comprising:

an array of a plurality of solar cell assemblies each including a solar cell, and electrically conductive members in the form of metallic foils connected to the solar cell

a heat dissipating layer formed of a synthetic resin containing a thermally conductive filler; and

a base plate to which each of the solar cell assemblies is fixed through the heat dissipating layer,

and wherein the solar cell of each solar cell assembly is embedded in the heat dissipating layer.

In the photovoltaic electric generator of concentrator type constructed according to the second aspect of this invention, the solar cell of each of the plurality of solar cell assemblies is embedded in the heat dissipating layer, so that the side surfaces of the solar cell are covered by and held in contact with the material of the heat dissipating layer. Namely, not only the lower surface but also at least a portion of each side surface of the solar cell are bonded to the heat dissipating layer, with a high degree of reliability at the interface between the solar cell and the heat dissipating layer. That is, it is not necessary to force the solar cell onto the base plate under a high pressure (e.g., higher than 20 atm.), for bonding the solar cell to the base plate so as to assure a high degree of reliability at the bonding interface. Thus, the present photovoltaic electric generator of concentrator type can be fabricated without a risk of cracking of the solar cell, while assuring a sufficient force of bonding between the solar cell and the heat dissipating layer. The term “embedded” is interpreted to mean positioning of the solar cell relative to the heat dissipating layer such that at least a portion of each of the side surfaces of the solar cell is covered by the material of the heat dissipating layer, with the lower surface of the solar cell being located below the surface of the heat dissipating layer which is remote from the base plate. Namely, the solar cell need not be entirely embedded in the heat dissipating layer, and a light receiving surface of the solar cell which is opposite to the above-indicated lower surface may be exposed.

The solar cell can be bonded to the base plate through the heat dissipating layer, without cracking of the solar cell, by immersing the solar cell in a liquefied mass of the material of the heat dissipating layer, and then curing the liquefied material under pressure and heat. This manner of bonding of the solar cell to be base plate permits a reliable bonding interface between the heat dissipating layer and the lower surface and at least a portion of the side surfaces of the solar cell, even where the thickness of the solar cell is comparatively small.

In one preferred form of the photovoltaic electric generator of concentrator type, the heat dissipating layer is formed of a material selected from a group consisting of a thermoplastic material; and a non-thermoplastic material a modulus of elasticity or coefficient of viscosity of which is lowered to a minimal value during a rise of a temperature of the non-thermoplastic material within a predetermined range in the process of heating of the non-thermoplastic material to cure the non-thermoplastic material. In this case, the solar cell is immersed in a liquefied mass of the material of the heat dissipating layer in the process of heating of the material to first liquefy the material, and then cure the material under pressure, so that the solar cell is embedded in the cured mass of the material of the heat dissipating layer bonded to the base plate.

Preferably, the above-indicated non-thermoplastic material is a thermosetting resin, such as a liquid epoxy resin.

The second object indicated above may also be achieved according to a third aspect of this invention, which provides a photovoltaic electric generator of concentrator type comprising:

an array of a plurality of solar cell assemblies each including a solar cell, and electrically conductive members in the form of metallic foils;

a heat dissipating layer formed of a synthetic resin containing a thermally conductive filler; and

a base plate to which each of the solar cell assemblies is fixed through the heat dissipating layer,

and wherein the heat dissipating layer consists of a first layer, and a second layer located on one of opposite sides of the first layer which is remote from the base plate, the second layer being formed of a material selected from a group consisting of: a thermoplastic material; and a non-thermoplastic material a modulus of elasticity or coefficient of viscosity of which is lowered below that of the first layer during a rise of a temperature of the non-thermoplastic material within a predetermined range in the process of heating of the material to cure the non-thermoplastic material.

In the photovoltaic electric generator according to the third aspect of the invention, the heat dissipating layer consists of a first layer formed on the side of the base layer, and a second layer formed on the side of the solar cell, and the second layer is formed of a thermoplastic material, or a non-thermoplastic material whose modulus of elasticity or coefficient of viscosity is lowered below that of the first layer during a temperature rise of the non-thermoplastic material within a predetermined range in the process of heating of the non-thermoplastic material to cure the material. To bond each solar sell assembly to the base plate through the heat dissipating layer, the modulus of elasticity or coefficient of viscosity of the material of the second layer is lowered when the material is heated (to the predetermined temperature, where the material is the non-thermoplastic material). Thus, the material of the second layer is first liquefied by heating, and the solar cell is immersed in the liquefied mass of the material. The material is cured by further heating to its curing temperature. At this time, the first layer functions as the buffer layer, so that the solar cell can be suitably fixed to the base plate through the heat dissipating layer, even where the solar cell has a comparatively small thickness or some degree of undulation on its surface opposite to the base plate. In the present photovoltaic electric generator, the solar cell can be bonded to the base plate through the heat dissipating layer, without a risk of cracking of the solar cell, and with a sufficiently large force of bonding therebetween.

In one preferred form of the photovoltaic electric generator according to the third aspect of this invention, the solar cell of each solar cell assembly is embedded in the second layer of the heat dissipating layer. Since the modulus of elasticity or coefficient of viscosity of the material of the second layer is lowered during heating of the material to bond the solar cell to the base plate, the solar cell can be easily embedded in the heat dissipating layer.

In a second preferred form of the photovoltaic electric generator according to the third aspect of the invention, the first layer of the heat dissipating layer is formed of a thermosetting resin, and the non-thermoplastic resin of the second layer is a thermosetting resin. In a third preferred form of the photovoltaic electric generator of the third aspect of the invention, the first layer is formed of a solid epoxy resin, while the second layer is formed of a liquid epoxy resin. Namely, the first layer of the heat dissipating layer is preferably formed of a synthetic resin such as a solid epoxy resin, and the second layer is preferably formed of a synthetic resin such as a liquid epoxy resin. These solid and liquid epoxy resins are both thermosetting resins, and the dynamic viscoelasticity of these thermosetting resins exhibit temperature dependency as shown in FIG. 17, during a temperature rise in the process of heating to cure the resins. Namely, the modulus of elasticity and coefficient of viscosity of the solid epoxy resin simply increase with a rise of its temperature, while the modulus of elasticity and coefficient of viscosity of the liquid epoxy resin first decrease with a rise of its temperature up to a value between about 80° C. and about 100° C., and then increases with a further rise of the temperature. That is, the modulus of elasticity or coefficient of viscosity of the liquid epoxy resin is lowered down to a minimal value during a rise of its temperature within a predetermined range in the process of heating of the liquid epoxy resin to the curing temperature. During the temperature rise within the predetermined range to heat the materials of the heat dissipating layer for bonding the solar cell and the electrically conductive members to the base plate, the material of the second layer of the heat dissipating layer is liquefied while the material of the first layer maintains a relatively high modulus of elasticity. In this liquefied state of the material of the second layer, the solar cell and the electrically conductive members are immersed or embedded in the liquefied material. In the presence of the first layer on the side of the base plate, the solar cell and the electrically conductive members are prevented from contacting the base plate, so that an otherwise possible loss of electrical insulation is prevented. The material once liquefied is solidified into the cured second layer as the temperature is further raised. In this manner, the solar cell can be suitably fixed to the base plate through the heat dissipating layer.

The second object indicated above may be achieved according to a fourth aspect of this invention, which provides a photovoltaic electric generator of concentrator type comprising:

an array of a plurality of solar cell assemblies each including a solar cell, and electrically conductive members in the form of metallic foils;

a heat dissipating layer formed of a synthetic resin containing a thermally conductive filler; and

a base plate to which each of the solar cell assemblies is fixed through the heat dissipating layer,

and wherein sad metallic foils have a plurality of voids and are at least partially embedded in the heat dissipating layer such that the plurality of voids are filled with a material of the heat dissipating layer.

In the photovoltaic electric generator of concentrator type constructed according to the fourth aspect of this invention, the metallic foils have a plurality of voids, and are at least partially embedded in the heat dissipating layer such that the voids formed in the foils are filled with the material of the heat dissipating layer. In the presence of the voids filled with the material of the heat dissipating layer, the metallic foils and the heat dissipating layer are securely bonded together, by a so-called “anchoring effect”, so that the solar cell having a comparatively small thickness can be suitably bonded to the base plate through the heat dissipating layer, without a risk of cracking of the solar cell, and with a sufficiently large force of bonding therebetween.

In one preferred form of the photovoltaic electric generator according to any one of the second, third and fourth aspects of the invention described above, the solar cell has a light-receiving surface, and the electrically conductive members in the form of metallic foils extend outwardly from a periphery of the solar cell in a plane parallel to the light receiving surface. In this arrangement, a residual stress generated in the process of bonding the electrically conductive members to the solar cell is considered to be evenly distributed by a stress generated in the process of bonding the solar cell to the base plate, so that the risk of cracking of the solar cell is effectively reduced.

In another preferred form of the photovoltaic electric generator, the solar cell has a light-receiving surface, and each of the plurality of solar cell assemblies further includes a sealing layer which is formed of a transparent resin and which covers the light-receiving surface. In this arrangement, a residual stress of the solar cell is reduced owing to the sealing layer which covers the light-receiving surface.

In one advantageous arrangement of the preferred form of the photovoltaic electric generator described just above, the sealing layer has a light-receiving surface, and each of the plurality of solar cell assemblies further includes a transparent glass plate which covers the light-receiving surface of the sealing layer. The transparent glass plate protects the sealing layer and the solar cell against exposure to water and reaction gases, and provides a flat light-receiving surface.

In a further preferred form of the photovoltaic electric generator, the solar cell has a light-receiving surface and at least one electrode formed on the light-receiving surface, and the electrically conductive members in the form of metallic foils include at least one foil which is soldered to the at least one electrode such that the at least one foil is inclined at a predetermined angle with respect to an upper surface of the at least one electrode. This arrangement prevents a drooping flow of a solder onto the side surfaces of the solar cell in the process of soldering of the metallic foil to the electrode with the solder, making it possible to prevent short-circuiting of the electrically conductive member in the form of a metallic foil.

Preferably, the metallic foil is positioned relative to the corresponding electrode formed on the light-receiving surface of the solar cell, such that the extreme end of the metallic foil soldered to the electrode is spaced a suitable distance from an outer edge of the electrode, inwardly of the light-receiving surface. In this case, the solder may remain in a relatively ample space between the lower surface of the end portion of the metallic foil and the upper surface of the electrode, and is prevented from drooping down from the electrode onto the side surfaces of the solar cell.

### BRIEF DESCRIPTION OF THE DRAWINGS

The above and other objects, features, advantages and technical and industrial significance of the present invention will be better understood by reading the following detailed description of preferred embodiments of the invention, when considered in connection with the accompanying drawings, in which:

FIG. 1 is an exploded elevational view in cross section of a solar cell assembly including a solar cell and an electrode structure constructed according to one embodiment of this invention;

FIG. 2 is an elevational view in cross section of the solar cell assembly;

FIG. 3 is a perspective view of the solar cell assembly;

FIG. 4A is an elevational view in cross section of the solar cell assembly in the process of being bonded to a heat dissipating plate;

FIG. 4B is an elevational view in cross section of the solar cell assembly in the process following the process of FIG. 4A;

FIG. 5 is a perspective view of a known solar cell assembly having a conventional electrode structure;

FIG. 6 is a perspective view of the know solar cell assembly, showing deformation of the solar cell upon connection of a lower lead electrode to the solar cell;

FIG. 7 is a perspective view of the known solar cell assembly, showing deformation of the solar cell upon connection of upper lead electrodes to the solar cell;

FIG. 8A is a perspective view of the known solar cell assembly, showing cracking at the junction between the upper lead electrodes and the solar cell, due to a shear stress generated in the conventional electrode structure;

FIG. 8B is a flow chart illustrating a process of forming the solar cell assembly of FIG. 1 and fixing the solar cell assembly to a base plate;

FIG. 9 is a perspective view of a photovoltaic electric generator of concentrator type constructed according to another embodiment of this invention, and a sun tracking device operatively connected to the photovoltaic electric generator;

FIG. 10A is a plan view of a the photovoltaic electric generator of FIG. 9;

FIG. 10B is a schematic view of the photovoltaic electric generator in cross section taken along a one-dot chain line of FIG. 10A;

FIG. 11 is a view illustrating one of solar cell assemblies incorporated in the photovoltaic electric generator of FIG. 10A;

FIG. 12A is a plan view showing the solar cell assembly of FIG. 11 fixed to a base plate through a heat dissipating layer;

FIG. 12B is an elevational view of the solar cell assembly of FIG. 11 in cross section taken along one-dot chain line of FIG. 12A;

FIG. 12C is a bottom plan view of the solar cell assembly, with the base plate and heat dissipating layer being removed;

FIG. 13 is a view showing in detail an upper electrode of a solar cell assembly and a metallic foil which are soldered to each other, in the prior art;

FIG. 14 is a view showing in detail an upper electrode of the solar cell assembly and a metallic foil which are soldered to each other in the according to the embodiment of the invention;

FIG. 15 is a view showing in detail the upper electrode of the solar cell assembly and the metallic foil which are soldered to each other in another embodiment of this invention;

FIG. 16 is a view showing in detail the upper electrode of the solar cell assembly and the metallic foil which are soldered to each other in a further embodiment of this invention; and

FIG. 17 is a graph indicating temperature dependency of modulus of elasticity and coefficient of viscosity of solid and liquid epoxy resins used as the heat dissipating layer of the solar cell assembly.

### DETAILED DESCRIPTION OF THE PREFERRED EMBODIMENT

There will be described in detail some preferred embodiments of this invention, referring to the accompanying drawings. It is noted that the drawings are simplified to schematically illustrate the embodiments of the invention, and do not accurately represent the dimensional ratios and configurations of various elements shown in various figures of the drawings

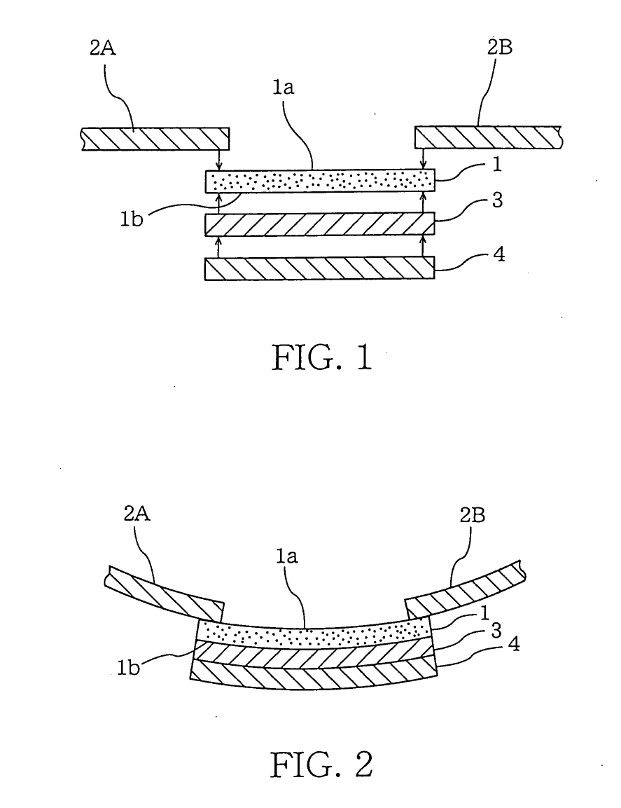

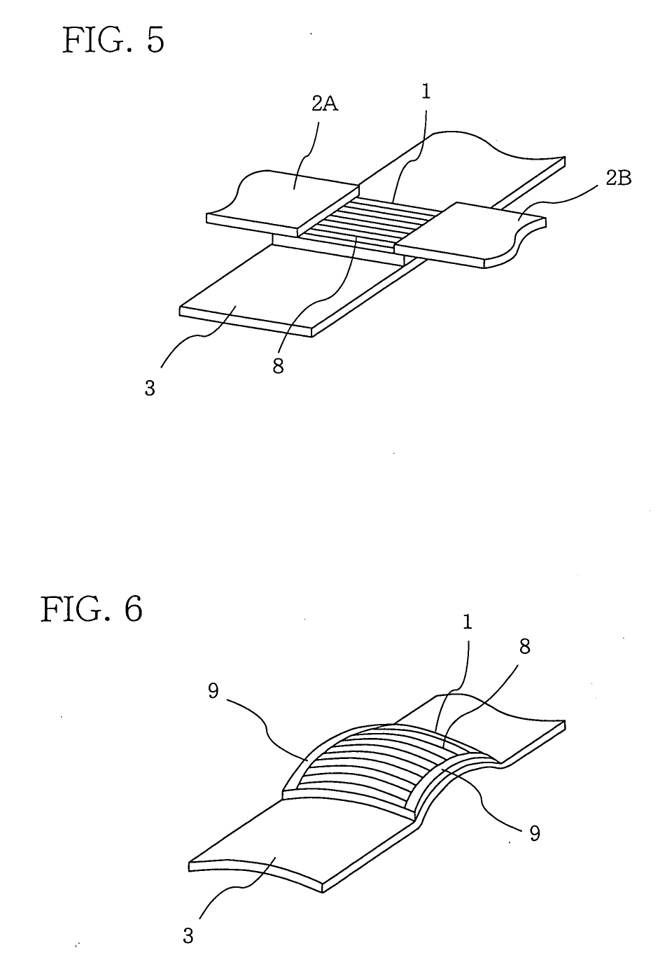

Referring first to the exploded cross sectional view of FIG. 1, there is shown one embodiment of a solar cell assembly, which has an improved electrode structure. The solar cell assembly includes a solar cell 1 having an upper surface 1a. On the opposite end portions of the upper surface 1a, there are formed two upper electrodes in the form of two elongate bus-bar electrodes 9, as shown in FIG. 6, such that the two bus-bar electrodes 9 extend along the respective edges of the opposite end portions. A pair of first electrodes (electrically conductive members) in the form of two upper lead electrodes 2A and 2B formed from copper sheets are soldered at one of their opposite end portions to the respective two elongate bus-bar electrodes 9, as shown in FIG. 1. The solar cell 1 further has a lower surface 1b on which there is formed a lower electrode (indicated at 58 in FIG. 11), which is soldered over its entire lower surface to a second electrode (electrically conductive member) in the form of a lower lead electrode 3, as also shown in FIG. 5. To the lower surface of the lower lead electrode 3 which is remote from the solar cell 1, there is soldered a metallic sheet or backing plate 4, which has substantially the same dimension in the right and left direction as seen in FIG. 1, that is, in the longitudinal direction of the upper lead electrodes 2A, 2B.

The solar cell 1 is a sheet formed of Ge having a thickness of 0.15-0.17 mm, for example. The upper lead electrodes 2A, 2B and the lower lead electrode 3 are sheets formed of copper having a thickness of 0.1 mm, for example. The surfaces of each of these lead electrodes 2A, 2B, 3 are covered with plating films of a suitable solder having a thickness of about 40 μm, for example. The metallic sheet 4 has a thickness of about 1 μm, for example, and is formed of 42 wt. % Ni—Fe alloy, and the surfaces of the metallic sheet 4 are covered with plating films of Sn having a thickness of about 1 μm, for example. The metallic sheet 4 has a thermal expansion coefficient which is almost equal to that of the solar cell 1 and is about one tenth of that of the lower lead electrode 3 formed of Cu.

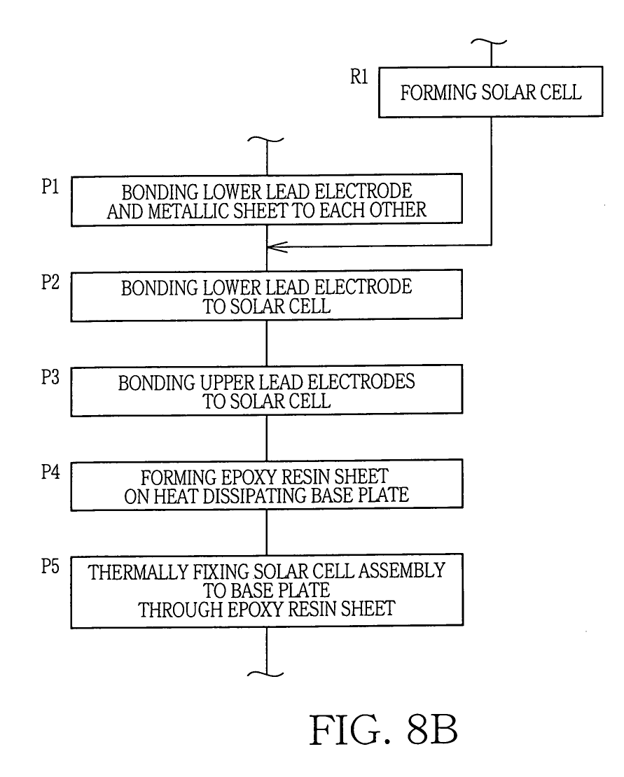

The solar cell assembly constructed as described above is formed by a process illustrated in the flow chart of FIG. 8B. Initially, step P1 is implemented to solder or otherwise bond the separately formed lower lead electrode 3 and metallic sheet 4 to each other. In the meantime, the solar cell 1 is formed in step R1, by a semiconductor fabricating process as well known in the art, such that the upper electrodes in the form of the bus-bar electrodes 9 are formed on the upper surface of the solar cell 1, which functions as the light-receiving surface, while the lower electrode (not shown) is formed on the lower surface of the solar cell 1. Then, step P2 is implemented to bond, by soldering for example, the solar cell 1 to the upper surface of the lower lead electrode 3 which is remote from the metallic sheet 4. Thus, the lower electrode of the solar cell 1 is electrically connected to the lower lead electrode 3.

Since the solar cell 1, lower electrode 3 and metallic sheet 4 have the thickness dimensions and thermal expansion coefficient values described above, the solar cell 1 is deformed into a part-spherical shape, with its opposite major surfaces being convexed downwardly, as shown in FIG. 2, in the process of a temperature drop of the solar cell 1, lower lead electrode 3 and metallic sheet 4, after the metallic sheet 4 is soldered to the lower surface of the lower lead electrode 3.

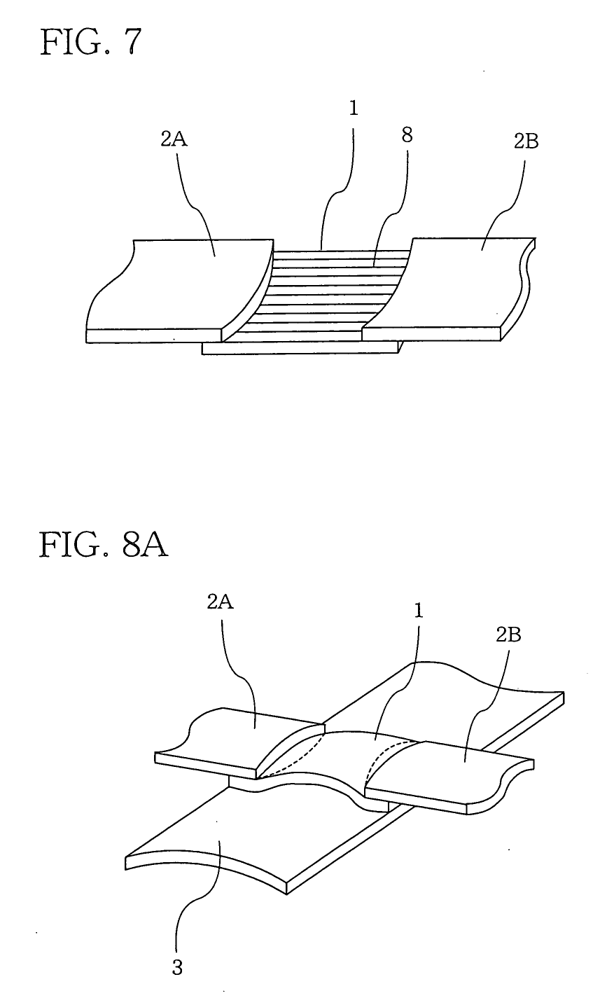

Then, step P3 is implemented to solder or otherwise bond the upper lead electrodes 2A, 2B to the upper electrodes 9 of the solar cell 1 which has been bonded to the lower lead electrode 3. As described above by reference to FIG. 7, the upper lead electrodes 2A, 2B are deformed into an almost part-cylindrical shape, with their major surfaces being convexed downwardly, in the process of a temperature drop of the solar cell 1 after the upper lead electrodes 2A, 2B are soldered to the opposite end portions of the upper surface la of the solar cell 1. Thus, both of the solar cell 1 and the upper lead electrodes 2A, 2B soldered to the solar cell 1 are deformed in the same direction. Accordingly, the provision of the metallic sheet 4 makes it possible to prevent generation of a shear stress at or near the junction between the solar cell 1 and the upper lead electrodes 2A, 2B.

Although the steps P1, P2 and P3 of the process illustrated in the flow chart of FIG. 8B are implemented in the order of description, these steps may be implemented in any other order, provided the step PI is not implemented as the last step of those steps P1-P3. For instance, those three steps are implemented in any one of the following orders: P1→P3→P2; P3→P1→P2; and P2→P1→P3. Alternatively, the steps P1-P3 are implemented concurrently, by superposing the upper lead electrodes 2A, 2B, the solar cell 1, the lower lead electrode 3 and the metallic sheet 4 on each other, and heating a thus formed laminar structure of the solar cell assembly. Further alternatively, the step P2 is followed by the steps P1 and P3 which are implemented concurrently, so that the upper lead electrodes 2A, 2B are bonded to the solar cell 1 while the metallic sheet 4 is bonded to the lower lead electrode 3. Still alternatively, the step P3 is followed by the steps P1 and P2, which are implemented concurrently, so that the lower lead electrode 3 and the metallic sheet 4 are concurrently bonded to the solar cell 1 and the lower lead electrode 3, respectively. In any of the alternative cases described above, the shear stress of the solar cell 1 conventionally generated due to the bonding of the upper lead electrodes 2A, 2B and the lower lead electrode 3 to the solar cell 1 can be reduced or eliminated, since the deformation of the solar cell 1 during a temperature drop to the ambient level after the bonding of the upper lead electrodes 2A, 2B and the deformation of the solar cell 1 during a temperature drop to the ambient level after the bonding of the lower lead electrode 3 take place in the same direction.

The amount of deformation of the solar cell 1 into the downwardly convex part-spherical shape can be controlled by adjusting the thickness of the metallic sheet 4. The dimensions of the metallic sheet 4 other the thickness are preferably almost equal to or slightly larger than those of the solar cell 1. The thickness of the metallic sheet 4 may be determined so that the solar cell 1 is kept substantially planar, without substantive downwardly convex deformation in the process of the temperature drop after the soldering of the metallic sheet 4 to the lower electrode 3. In this case, too, the metallic sheet 4 is more or less effective to prevent cracking of the solar cell 1.

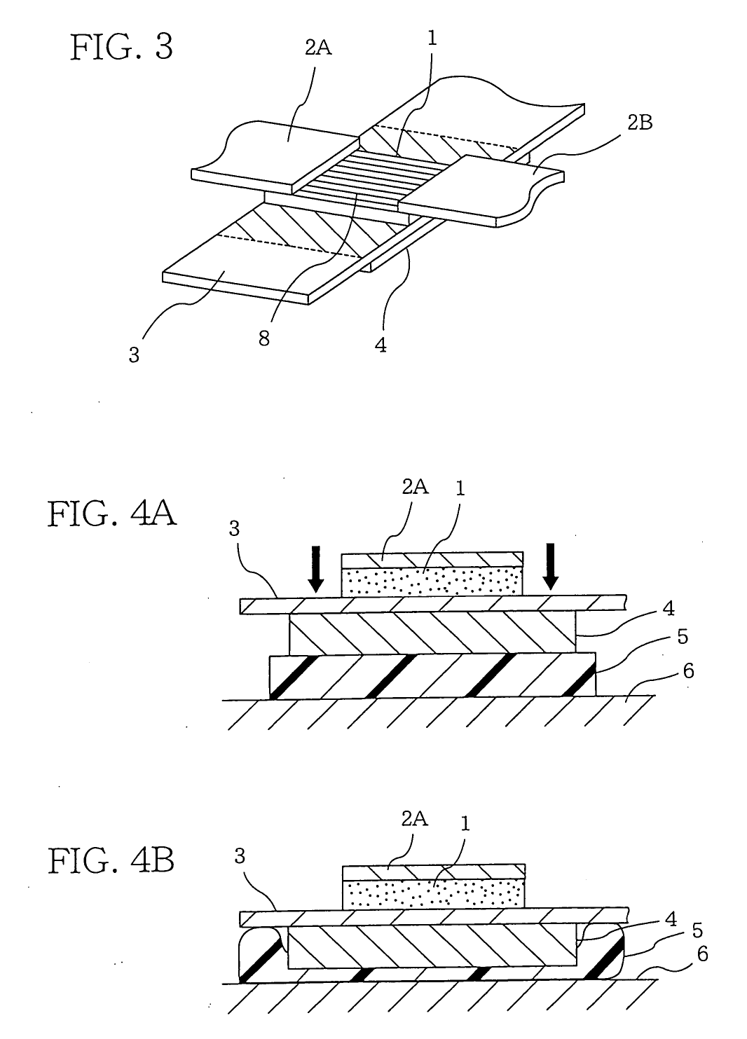

Referring to the perspective view of FIG. 3, there is shown the electrode structure in the solar cell assembly, after the upper lead electrodes 2A, 2B are soldered to the upper surface 1a of the solar cell 1 and after the lower electrode 3 and the metallic sheet 4 are soldered to the lower surface 1b of the solar cell 1. As shown in FIG. 3, the metallic sheet 4 has a larger dimension than the solar cell 1 in the longitudinal direction of the lower electrode 3, and extends sideways by a suitable distance from the opposite ends of the solar cell 1 which are opposite to each other in the longitudinal direction of the lower electrode 3. Thus, the metallic sheet 4 has a major surface area larger than the area of the upper and lower surfaces 1a, 1b of the solar cell 1. The metallic sheet 4 and the solar cell 1 are substantially aligned or centered with each other, in a plane parallel to the upper and lower surfaces 1a, 1b.

In the process of FIG. 8B, the step P3 is followed by step P4 to form an epoxy resin sheet 5 on a heat dissipating plate or base plate 6 on which the solar cell assembly is fixed. The epoxy resin sheet 5 may be first formed and then bonded to the upper surface of the heat dissipating plate 6, or may be formed directly on the upper surface of the plate 6. Then, step P5 is implemented to first place the solar cell assembly consisting of the solar cell 1, upper and lower lead electrodes 2A, 2B, 3 and metallic sheet 4, on the epoxy resin sheet 5, and then force the solar cell assembly onto the plate 6 via the epoxy resin sheet 5, while heating the epoxy resin sheet 5, so that the solar cell assembly is thermally bonded to the plate 6 through the epoxy resin sheet 5.

Referring next to the elevational view of FIGS. 4A and 4B in cross section taken in a plane perpendicular to the light-receiving surface 1a of the solar cell 1 and parallel to the longitudinal direction of the lower lead electrode 3, there will be described a method of bonding the solar cell assembly to the heat dissipating plate 6. It is noted that the ratios of the thickness values of the solar cell 1 and the upper and lower lead electrode 2A and 3, etc. as shown in FIGS. 4A and 4B are almost equal to the actual values. For the purpose of dissipating heat from the solar cell assembly, the solar cell assembly is bonded through the epoxy resin sheet 5 to the heat dissipating plate 6, which is formed of aluminum and has a thickness of about 4 mm, for example.

Normally, the epoxy resin sheet 5 has a thickness of about 0.35 mm. For maximizing the efficiency of heat dissipation from the solar cell assembly, however, it is necessary to minimize the thickness of the epoxy resin sheet 5. To this end, the epoxy resin sheet 5 interposed between the metallic sheet 4 and the heat dissipating plate 6 is heated for about 30 minutes to raise its temperature to 175° C., for example, and compressed to a reduced thickness of 0.1 mm or smaller. In this operation to bond the solar cell assembly to the heat dissipating plate 6, the solar cell assembly is forced downwards at portions (hatched areas shown in FIG. 3) of the upper surface of the lower lead electrode 3, as indicated by arrows in FIG. 4A, that is, at portions of the upper surface of the lower lead electrode 3 which are adjacent to the opposite end faces of the solar cell 1 which are opposite to each other in the longitudinal direction of the lower lead electrode 3. This manner of forcing the solar cell assembly prevents damaging of the solar cell 1 in the process of bonding to the heat dissipating plate 6. In the present embodiment wherein the metallic sheet 4 extends from the above-indicated opposite end faces of the solar cell 1 in the longitudinal direction of the lower lead electrode 3, the portions of the lower lead electrode 3 at which the solar cell assembly is forced downwards are supported or backed by the opposite end portions of the metallic sheet 4, so that a portion of the epoxy resin sheet 5 located under the metallic sheet 4 is compressed or compacted via the metallic sheet 4, when the solar cell assembly is forced downwards at the above-indicated portions of the lower lead electrode 3. Thus, the thickness of the epoxy resin sheet 5 located below the metallic sheet 4 can be reduced from the nominal value of 0.35 mm to 0.1 mm or smaller at the compressed portion located right below the solar cell 1, as shown in FIG. 4B. The thus compressed portion of the epoxy resin sheet 5 has a sufficiently reduced thermal resistance, and permits efficient heat dissipation from the solar cell assembly into the heat dissipating plate 6.

As described above, the electrode structure of the solar cell assembly according to the present embodiment of the invention is arranged to prevent or minimize a risk of cracking of the solar cell 1 upon soldering of the lead electrodes 2A, 2B, 3 to the solar cell 1.

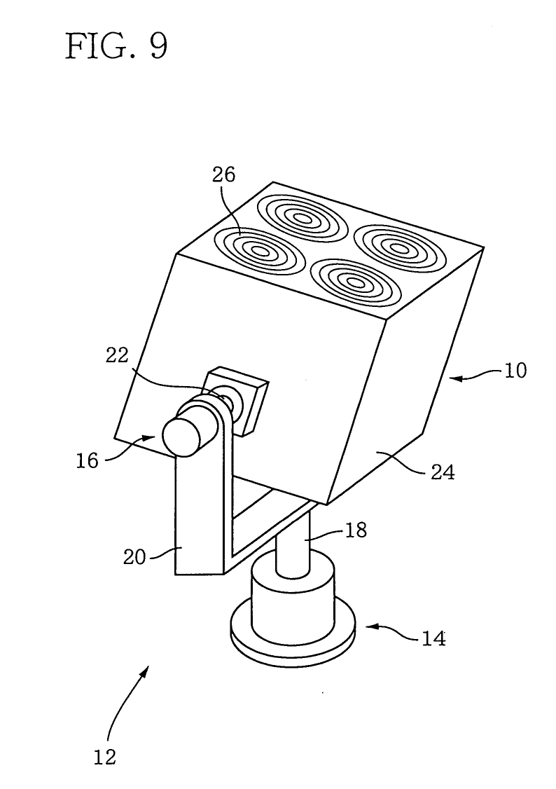

Referring next to the perspective view of FIG. 9, there are shown a photovoltaic electric generator 10 of concentrator type constructed according to another embodiment of the present invention, and a sun tracking device 12. The photovoltaic electric generator 10 includes an array or package of a plurality of solar cell assemblies each having a solar cell and an improved electrode structure, which have been described above with respect to the first embodiment. The sun tracking device 12 includes a vertical-axis drive device 14 and a horizontal-axis drive device 16 which are arranged to support the photovoltaic electric generator 10 such that the photovoltaic electric generator are rotatable about an vertical axis and a horizontal axis, so that a surface of the photovoltaic electric generator 10 in which a plurality of non-imaging Fresnel lenses 26 are exposed is inclined so as to track the sun, so that the rays from the sun are most effectively incident upon the Fresnel lenses 26. The horizontal and vertical-axis drive devices 14 and 16 are operable to rotate the photovoltaic electric generator 10 about the respective vertical and horizontal axes which are perpendicular to each other. The vertical-axis drive device 14 includes a vertical shaft 18 extending in the vertical direction and rotatable about the vertical axis, a drive device for rotating the vertical shaft 18, and a U-shaped lever 20 fixed to the vertical shaft 18, while the horizontal-axis drive device 16 includes a horizontal shaft 22 extending in the horizontal direction and supported by free ends of a pair of arms of the U-shaped lever 20 such that the horizontal shaft 22 is rotatable about the horizontal axis by a drive device which is supported by one of the arms of the U-shaped lever 20 and which is connected to the horizontal shaft 22 either directly or via a suitable speed reducer.

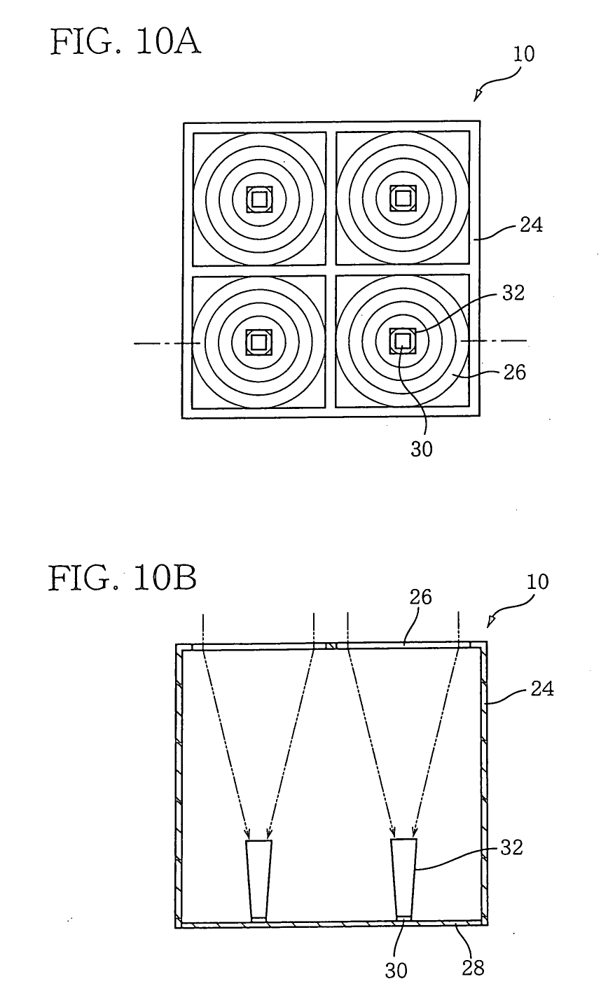

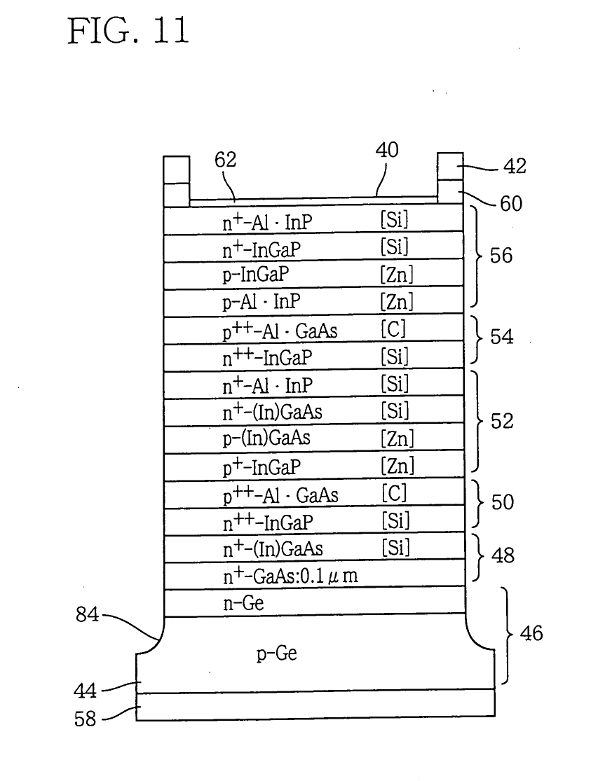

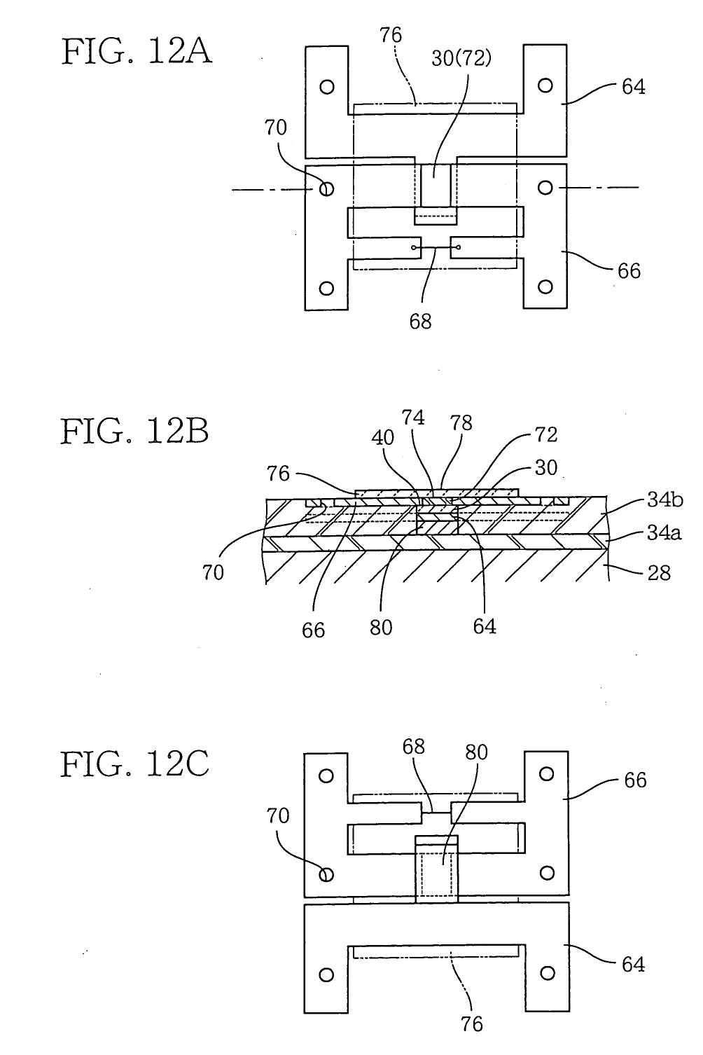

The arrangement of the photovoltaic electric generator 10 of concentrator type is shown in the plan view of FIG. 10A, and in the schematic elevational view of FIG. 10B in cross section taken along the one-dot chain line in FIG. 10A. As shown in these figures, the photovoltaic electric generator 10 includes: a casing 24 of rectangular box construction formed of a plastic material, for example; an array of the above-indicated non-imaging Fresnel lenses 26 which functions as a primary optical system and which is accommodated in an upper lid portion of the casing 24; a base plate 28 which is disposed in a bottom portion of the casing 24 and which is formed of an aluminum alloy (a major component of which is aluminum); the above-indicted array of solar cell assemblies each of which includes a solar cell 30 and is bonded to a base plate 28 via a heat dissipating layer 34 which will be described in detail by reference to FIG. 12B; and a plurality of hollow reflector mirrors 32 which function as a secondary optical system and which are disposed on the respective solar cells 30. The Fresnel lenses 26 function to concentrate the received solar radiation on a light-receiving surface 40 (shown in FIG. 11) of the solar cells 30. The base plate 28 is a planar member formed of an aluminum alloy such as A5203P according to JIS-H4000, and has a thickness of about 2-5 mm.

In the photovoltaic electric generator 10 of concentrator type constructed as described above, the solar radiation received by each Fresnel lens 26 is incident upon the light-receiving surface 40 of the corresponding solar cell 30 through the corresponding hollow reflector mirror 32, as indicated by two-dot chain lines in FIG. 10B, and an electric energy is generated by the solar cell 30. In the present photovoltaic electric generator 10 which employs the Fresnel lenses 26 of non-imaging type, the intensity of the solar radiation incident upon the light-receiving surface 40 of each solar cell 30 is held substantially constant, provided the angle of a straight line perpendicular to the plane of each Fresnel lens 26 with respect to a straight line connecting the Fresnel lens 26 and the sun is held within a predetermined angular range. Each of the hollow reflector mirrors 32 may be a hollow prism which has a hexagonal shape in transverse cross section, and an upper open end and a lower open end that serve as an optical inlet and an optical outlet, respectively. This reflector mirror 32 in the form of the hollow hexagonal prism has inner mirror surfaces having a reflectance of about 95%. A part of the solar radiation received by the Fresnel lens 26 and passed into the reflector mirror 32 is reflected by the inner mirror surfaces of the reflector mirror 32, and is incident upon the light-receiving surface 40 of the corresponding solar cell 30, so that chromatic aberration generated by the Fresnel lens 26 is removed or rectified, and the solar radiation received by the Fresnel lens 26 can be directed to be incident upon the light-receiving surface 40, even where the photovoltaic electric generator 10 is not accurately oriented with respect to the sun by the sun tracking device 12. Accordingly, the hollow reflector mirrors 32 are effective to prevent deterioration of the electrode structure (electrically conductive members) due to unintended exposure of the electrode structure to the solar radiation.

Reference is now made to FIG. 11 showing one of the solar cell assemblies of the photovoltaic electric generator 10. As shown in FIG. 11, the solar cell 30 of each solar cell assemblies has a multi-junction semiconductor structure consisting of a plurality of p and n layers which are laminated on each other and which have respective different ranges of absorption wavelength. This multi-junction structure consists of: a lower junction layer 46 constituted by a p-type substrate 44 formed of Ge; a buffer layer 48 formed on the substrate 44; a first tunnel layer 50 formed on the buffer layer 48; an intermediate junction layer 52 formed on the first tunnel layer 50; a second tunnel layer 54 formed on the intermediate junction layer 52; and an upper junction layer 56 formed on the second tunnel layer 54. The lower junction layer 46 is constituted by a lower portion of the p-type Ge substrate 44, and an n-type Ge layer formed by diffusion of impurities into an upper portion of the GE substrate 44. The buffer layer 48 consists of a lower n⁺-GaAs layer and an upper n⁺-(In)GaAs layer. The first tunnel layer 50 consists of a lower n⁺⁺-InGaP layer and an upper p⁺⁺-AlGaAs layer. The intermediate junction layer 52 consists of a lowermost p₊-InGaP layer, an intermediate p-(In)GaAs layer, another intermediate n⁺-(In)GaAs layer and an uppermost n⁺-AlInP layer. The second tunnel layer 54 consists of a lower n⁺⁺-InGaP layer and an upper p₊₊-AlGaAs. The upper junction layer 56 consists of a lowermost p-AlInP layer, an intermediate p-InGaP layer, another intermediate n⁺-InGaP layer and an uppermost n⁺-AlInP layer. The lower electrode 58 indicated above is bonded to the lower surface of the Ge substrate 44 (lower junction layer 46). On opposite end portions of an upper surface of the uppermost n⁺-AlInP layer of the upper junction layer 56, there are formed two contact layers 60 in the form of In₊-(In)GaAs layers, for example. On the other exposed portion of the upper surface of the uppermost n⁺-AlInP layer of the upper junction layer 56, there is formed an anti-reflection layer 62. On the two contact layers 60, there are formed respective two upper electrodes in the form of two elongate bus-bar electrodes 42 are opposed to and spaced apart from each other, so as to permit the upper surface of the anti-reflection layer 62 to serve as the light-receiving layer 40 of the solar cell 30. In the semiconductor structure shown in FIG. 11, elements indicated in the brackets [ ] in the figure, such as Si and Zr, are used as impurities diffused or ion-injected into the appropriate layers to make these layers to be semiconductive. The semiconductor structure of the solar cell 30 is subjected to an etching operation to remove a peripheral portion to a suitable depth from the light-receiving surface 40, so as to form a mesa portion 84.

The pn junctions provided the lower, intermediate and upper junction layers 46, 52 and 56 are electrically connected in series to each other, and have respective different ranges of center wavelength. For instance, the upper junction layer 56 absorbs blue rays in the wavelength range of 300-600 nm, and the intermediate junction layer 52 absorbs yellow rays in the wavelength range of 600-1000 nm, while the lower junction layer 46 absorbs red rays in the wavelength range of 1000-1800 nm. Thus, the solar cell 30 as a whole is arranged to absorb a wide spectrum of wavelength of the solar radiation, permitting a high degree of efficiency of conversion from the solar radiation energy into the electric energy.

FIG. 12A is a plan view showing the solar cell assembly of FIG. 11 fixed to the above-indicated base plate 28 through the above-indicated heat dissipating layer 34, and FIG. 12B is an elevational view of the solar cell assembly of FIG. 11 in cross section taken along one-dot chain line of FIG. 12A, while FIG. 12C is a bottom plan view of the solar cell assembly, with the base plate 28 and heat dissipating layer 34 being removed. As shown in these figures, each solar cell assembly of the photovoltaic electric generator 10 is connected, at its lower electrode 58 fixed to the lower surface of the solar cell 30, to a Y-shaped metallic foil 64, and at its two elongate upper electrodes 42 fixed to the upper surface of the solar cell 30, to a pair of separate F-shaped metallic foils 66. The lower electrode 58 is entirely covered by the lower portion of the letter Y of the Y-shaped metallic foil 64, while the two elongate upper electrodes 42 are covered by the free end portions of the longer horizontal strokes of the Letter F of the respective F-shaped metallic foils 66. Preferably, the Y-shaped metallic foil 64 extending from the lower electrode 58 of each solar cell 30 are electrically connected to the F-shaped metallic foils 66 extending from the upper electrodes 42 of the adjacent solar cell 30, so that the solar cells 30 of the adjacent solar cell assemblies of the photovoltaic electric generator 10 are electrically connected in series to each other. The relatively short horizontal strokes of the Letter F of the two F-shaped metallic foils 66 are connected to each other through a conductive wire 68. These metallic foils 64, 66 are copper foils having a thickness of about 0.1 mm, for example, and have a plurality of voids 70 such as through-holes and cutouts. The number and sizes of these voids 70 are determined such that the voids 70 do not have an adverse influence on the electrical conductivity of the foils 64, 66. In the specific examples of FIGS. 12A, 12B and 12C, the voids 70 are through-holes. The metallic foils 64, 66 have a lower electric resistance than ordinary metal wires, a reduced amount of power loss due to a flow of an electric current therethrough, and a reduced amount of generation of heat due to the Joule heat.

As shown in FIG. 12B, the solar cell assembly including the solar cell 30 is fixed to the base plate 28 via the heat dissipating layer 34, such that the solar cell 30 is at least partially, preferably entirely embedded in the heat dissipating layer 34 such that the light-receiving surface 40 is exposed. The heat dissipating layer 34 is formed of a synthetic resin in which is dispersed a powdered filler for improving the thermal conductivity of the heat dissipating layer 34. The filler may consist of at least one of a powder of carbon, a glass fiber, a powder of alumina (Al₂O₃) and a powder of a metallic material. Namely, the solar cell 30 is fixed to the heat dissipating layer 34, at the side surfaces as well as the lower surface. To this end, the solar cell 30 is immersed in a mass of the material of the heat dissipating layer 34 in a liquid state, and the material is cured by heating under an elevated pressure. In this manner, the solar cell 30 can be bonded to the heat dissipating layer 34, without a risk of cracking of the solar cell 30, even where the thickness of the solar cell 30 is comparatively small.

Preferably, the heat dissipating layer 34 consists of a first layer 34a formed on the base plate 28 and having a thickness of about 100 μm, and a second layer 34b formed on the first layer 34a and having a thickness of about 350 μm (about 150 μm after the curing). The second layer 34b is formed of a thermoplastic material, or a non-thermoplastic material which is gelled or liquefied, and modulus of elasticity or coefficient of viscosity of which is lowered below that of the first layer 34a, during a temperature rise of the non-thermoplastic material to a predetermined value in the process of heating to cure the thermoplastic material. For example, the first layer 34a is formed of a composition including as a major component a thermosetting resin such as an epoxy resin having a modulus of elasticity of about 6-9 GPa after the curing, while the second layer 34b is formed of a composition including as a major component a thermosetting resin having a modulus of elasticity of about 20-50 GPa after the curing, a minimum modulus of elasticity of about 0.01-1 GPa in the process of heating under pressure, and a minimum coefficient of viscosity of between about 5×10³Pa.s and about 5×10⁴Pa.s. Usually, the lower surface of the solar cell 30 on the side of the base plate 28 is roughened with minute undulation of about 20-40 μm in the presence of burrs generated in the process of soldering of the metallic foil 64 to the lower surface. Such undulation of the lower surface of the solar cell 30 may cause cracking of the solar cell 30 when the solar cell 30 is forced onto the base plate 28 to bond the solar cell 30 to the base plate 28. In the present embodiment, however, the second layer 34b is formed of a material having a high elasticity or viscoelasticity during a rise of a temperature of the second layer 34b within a predetermined range in the process of heating the non-thermoplastic material of the second layer 34b to cure the non-thermoplastic material, and the first layer 34a interposed between the second layer 34b and the base plate 28 functions as a buffer member, so that the solar cell 30 can be suitably bonded to the base plate 28 even where the solar cell 30 has a comparatively small thickness and some degree of undulation on its lower surface. Further, the heat dissipating layer 34, which has thermal conductivity of about 5.0 W/m.K, functions not only as a layer to effectively dissipate heat from the solar cell 30 heated by the incident solar radiation, but also as a bonding layer to bond the solar cell 30 to the base plate 28, and as an insulating layer for electrical insulation between the metallic foils 64, 66 and the base plate 28.

As shown in FIG. 12B, the metallic foil 64 is entirely embedded in the heat dissipating layer 34, and the metallic foil 66 is partly embedded in the heat dissipating layer 34, such that the voids 70 formed in the metallic foils 64, 66 are filled with the material of the heat dissipating layer 34, so that the metallic foils 64, 66 are securely fixed to the heat dissipating layer 34, with a so-called “anchoring effect”. Comparatively soft electrically conductive members such as copper foils are generally easily subject to a stress concentration at their ends upon application of a stress thereto, and may be removed from the mating surface, when a force as small as about 10 N/mm is applied to the conductive members. However, the arrangement according to the present embodiment is effective to prevent such a drawback, and assures improved stability of fixing of the solar cell 30 to the base plate 28.

As shown in FIGS. 12A and 12C, the electrically conductive members in the form of the metallic foils 64, 66 are disposed so as to radially extend outwardly of the solar cell 30, in a plane parallel to the light-receiving surface 40 of the solar cell 30. Usually, a solar cell is subjected to a compressive residual stress as a result of soldering of electrically conductive members to the solar cell. In the present embodiment wherein the electrically conductive members in the form of the metallic foils 64, 66 radially extend from the periphery of the solar cell 30, the compressive stress indicated above is considered to be evenly distributed owing to a tensile stress applied to the solar cell 30 when the solar cell 30 is fixed to the base plate 28. Thus, the solar cell 30 is effectively protected against cracking in the process of its fixing to the base plate 28, and an open-circuit voltage Voc and a curve fill-factor value (FF value) of the solar cell 30 can be improved. In addition, the cracking of the solar cell 30 in the process of curing of the material of the heat dissipating layer 34 is effectively prevented since the respective two upper electrodes 42 are connected to the respective two separate foils 66 that are electrically connected to each other by the conductive wire 68. If one-piece metallic foil is connected to the upper electrodes 42, and a portion of this one-piece metallic foil is embedded in the liquefied material of the heat dissipating layer 34, together with the solar cell 30, there is a relatively high risk of cracking of the solar cell 30 due to a stress which acts on the solar cell 30 in the process of curing of the material of the layer 34. In the present embodiment using the two separate metallic foils 66, the stress acting on the solar cell 30 in the process of curing of the material of the heat dissipating layer 34 is not likely to cause cracking of the solar cell 30, and is likely to be offset by the above-indicated compressive stress generated in the process of soldering of the foils 66 to the solar cell 30. Thus, the use of the two separate metallic foils 66 is advantageous.

Further, the light-receiving surface 40 of the solar cell 30 is covered by a transparent sealing layer 72 formed of a composition having a comparatively high degree of viscoelasticity, such as a copolymer of ethylene-vinyl acetate (EVA). In addition, a light-receiving surface 74 of the sealing layer 72 is covered by a transparent glass plate 76, as indicated by two-dot chain lines in FIGS. 12A and 12C, so as to maintain fluid tightness between the sealing layer 72 and the glass plate 76, for protecting the sealing layer 72 and the solar cell 30 against exposure to water and reaction gases. The transparent glass plate 76 has a flat upper surface serving as a light-receiving surface 78. Further, a backing plate 80 is interposed between the lower surface of the metallic foil 64 remote from the solar cell 30, and the first layer 34a of the heat dissipating layer 34. The backing plate 80 is formed of a nickel-iron alloy having a thermal expansion coefficient almost equal to that of the solar cell 30. In the arrangement described above, the residual stress at or near the light-receiving surface 40 is mitigated by the sealing layer 72, so that the curve fill-factor value (FF value) is improved. Further, the provision of the transparent glass plate 76 prevents deterioration of the above-indicated anti-reflection layer 62, even where the anti-reflection layer 62 consists of two films of ZnS—MgF₂ or is formed of a material which has an excellent anti-reflection property but a high degree of deliquescence. Namely, the transparent glass plate 76 is effective to improve the energy conversion efficiency of the solar cell 30 while assuring a long service life.

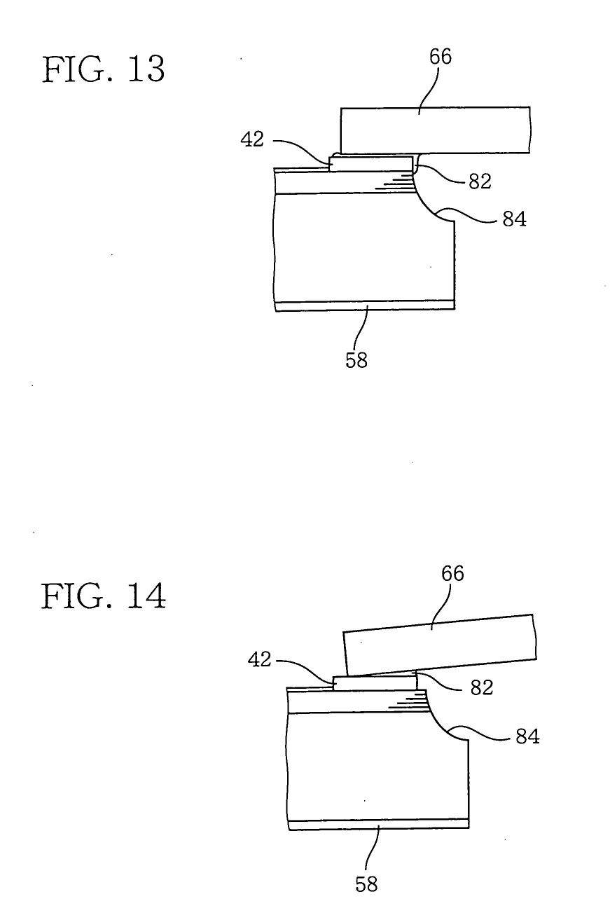

Referring next to FIG. 14, there is illustrated a manner in which one of the two metallic foils 66 is soldered to the corresponding one of the two upper electrodes 42. As shown in FIG. 14, the electrically conductive member in the form of the metallic foil 66 is soldered to the upper electrode 42, such that the metallic foil 66 is inclined at an angle of 2-3°, for example, with respect to the upper surface of the upper electrode 42. The upper electrode 42 is positioned on the upper surface of the solar cell 30 such that the end face of the upper electrode 42 on the outer side (right side as seen in FIG. 13) of the solar cell 30 is spaced from the corresponding peripheral edge of the upper surface by a distance of about 200 μm. In the known solar cell assembly, the electrically conductive member in the form of the metallic foil 66 is soldered to the upper electrode 42 such that the metallic foil 66 is parallel to the upper electrode 42, as shown in FIG. 13, so that there is a comparatively high risk of a drooping flow of a lead-containing solder 82 from the outer end face of the upper electrode 42 onto the surface of the mesa portion 84 of the semiconductor structure, resulting in short-circuiting of the electrically conductive member soldered to the upper electrode 42. In the arrangement shown in FIG. 14, however, the solder 82 remains between the metallic foil 66 and the upper electrode 42, without a drooping flow as experienced in the known solar cell assembly.

As described above, the solar cell 30 is embedded in the heat dissipating layer 34 such that the solar cell 30 is bonded at its lower and side surfaces to the heat dissipating layer 34, with a high degree of reliability at the interface between the solar cell 30 and the heat dissipating layer 34. Further, the solar cell 30 is immersed in a liquefied mass of the material of the heat dissipating layer 34, which is then cured or hardened under pressure and heat, so that the solar cell 30 having the comparatively small thickness can be suitably bonded to the base plate 28. That is, it is not necessary to force the solar cell 30 onto the base plate 28, with a large force, for bonding the solar cell 30 to the base plate 28. Thus, the photovoltaic electric generator 10 of concentrator type can be fabricated without a risk of cracking of the solar cell 30, while assuring a sufficient force of bonding between the solar cell 30 and the heat dissipating layer 34.

Further, the solar cell 30 can be bonded to the base plate 28 with high stability, even where the thickness of the solar cell 30 is comparatively small and even where the lower surface of the solar cell 30 has some degree of undulation, owing to the two-layered heat dissipating layer 34 which consists of the first layer 34a formed on the side of the base plate 28, and the second layer 34b which is formed, on the side of the solar cell 30, of a thermoplastic material, or a non-thermoplastic material whose modulus of elasticity or coefficient of viscosity is lowered below that of the first layer 34a during a temperature rise of the non-thermoplastic material in the process of heating of the non-thermoplastic material to cure the non-thermoplastic material. The material of the second layer 34b is first liquefied by heating, and the solar cell is immersed in the liquefied mass of the material. The material is cured by further heating to its curing temperature. Thus, the solar cell is embedded in the cured material of the second layer 34 bonded to the base plate 28. At this time, the first layer 34a functions as the buffer layer. An experiment revealed about 100% yield ratio of the solar cell assembly where the lower surface of the solar cell 30 on the side of the base plate 28 has undulation of about 140 μm. This yield ratio is considerably higher than the yield ratio of about 60% in the prior art in the case where the lower surface of the solar cell on the side of the base plate does not have undulation, and the yield ratio of about 0% in the prior art in the case where the lower surface of the solar cell has undulation of about 20 μm.

In addition, the electrically conductive member in the form of the metallic foils 64, 66 can be securely bonded to the solar cell 30 has a comparatively small thickness, owing to the so-called “anchoring effect” provided by the voids 70 which are filled with the material of the heat dissipating layer 34 in which the electrically conductive member is substantially embedded. A heat cycle test was conducted by repeating a heat cycle 500 times, such that specimens of the solar cell 30 were frozen to −40° C. and heated to 100° C. with a cycle time of about two hours. This heat cycle test revealed that about 80% of the specimens were free of removal or separation of the solar cell 30 from the base plate 28. A similar heat cycle test on the prior art specimens in which the solar cell 30 is bonded to the base plate 28 according to the prior art technique revealed that 100% of the specimens suffered from removal of the solar cell 30 from the base plate 28.

In addition, the electrically conductive member in the form of the metallic foils 64, 66 radially extends outwardly from the solar cell 30 in a plane parallel to the light-receiving surface 40. In this arrangement, the residual stress generated in the process of bonding the electrically conductive member to the solar cell 30 is considered to be evenly distributed by a stress generated in the process of bonding the solar cell 30 to the base plate 28, so that the risk of cracking of the solar cell 30 is effectively reduced. An experiment revealed no cracking of the specimens in the process of bonding of the solar cell 30 to the base plate 28, irrespective of the thickness values of the solar cell 30 of the specimens, and an average FF value of 0.86 in the case of solar radiation concentration of 70×. These results of the present embodiment are superior to about 40% cracking of the prior art specimens wherein the solar cell has a thickness of 150 μm, and an average FF value of 0.81 of the cracking-free prior art specimens in the case of solar radiation concentration of 70×.

Further, the residual stress of the solar cell 30 is reduced owing to the sealing layer 72 of a transparent resin which covers the light-receiving surface 40. An experiment revealed an average open-circuit voltage Voc of 2.89V, and an average FF value of 0.89 in the case of solar radiation concentration of 70×. These values are higher than an average open-circuit voltage Voc of 2.63V and an average FF value of 0.86 in the case of solar radiation concentration of 70× where the solar cell assembly is not provided with the sealing layer 72.

In addition, the transparent glass plate 76 covering the light-receiving surface 74 of the sealing layer 72 provides the light-receiving surface 78 which is highly flat, and protects the sealing layer 72 and the solar cell 30 against exposure to water and reaction gases. An experiment revealed that the solar cell 30 was not exposed to water after the solar cell 30 was left for about 500 hours in a pressure vessel at about 130° C. temperature and about 100 RH(%) humidity, and also revealed an increase of about 4% of a short-circuit current owing to the high degree of flatness of the light-receiving surface 78.

Further, the inclination of the metallic foils 66 with respect to the upper surface of the upper electrodes 42 formed on the upper surface of the solar cell 30 prevents a drooping flow of the solder 82 over the side surface of the solar cell 30 in the process of soldering of the metallic foils 66 to the upper electrodes 42, making it possible to prevent short-circuiting of the electrically conductive member in the form of the metallic foils 66. An experiment revealed complete freedom of the metallic foils 66 from the short-circuiting, contrary to about 10% short-circuiting in the prior art photovoltaic electric generator of concentrator type.

While some preferred embodiments of the present invention have been described above by reference to the drawings, it is to be understood that the present invention is not limited to the details of the illustrated embodiments.

In the solar cell assembly shown in FIGS. 1-4, the solar cell 1 is a sheet formed of Ge. However, the solar cell 1 may be formed of any other material such as Si or any other semiconductor or any compound semiconductor.

In the solar cell assembly of FIGS. 1-4, the lead electrodes 2A, 2B and 3 are sheets of Cu while the metallic sheet 4 is formed of 42 wt. % Ni—Fe alloy. However, the lead electrodes 2A, 2B, 3 may be formed of any other material (preferably, a metallic material) which has suitable values of electrical conductivity and thermal conductivity. Similarly, the metallic sheet 4 may be formed of any other metallic material which is selected depending upon the material of the lead electrodes 2A, 2B, 3 and which can reduce or eliminate the shear stress acting on the solar cell 1 and have sufficiently high electrical and thermal conductivity values.

While the metallic sheet 4 of the solar cell assembly of FIGS. 1-4 has substantially the same coefficient of thermal expansion as the solar cell 1, the coefficient of thermal expansion of the metallic sheet 4 may be smaller or larger than that of the solar cell 1, provided that the thermal expansion coefficient of the metallic sheet 4 is smaller than that of the lower lead electrode 3.

In the embodiment of FIGS. 1-4, the distances of extension of the opposite end portions of the metallic sheet 4 from the respective opposite ends of the solar cell 1 in the opposite directions parallel to the longitudinal direction of the lower lead electrode 3 are substantially equal to each other. That is, the metallic sheet is substantially aligned with the solar cell in the longitudinal direction of the lower lead electrode 3, in the solar cell assembly of FIGS. 1-4. However, the above-indicated distances need not be substantially equal to each other, as long as the metallic sheet has the opposite end portions extending from the respective ends of the solar cell in the longitudinal direction of the lower lead electrode 3. Further, the rectangular metallic sheet 4 may extend from the periphery of the solar cell 1 in all of the four directions corresponding to the respective four sides of the metallic sheet 4. It is also noted that the area of the opposite major surfaces of the metallic sheet 4 need not be larger than that of the solar cell 1.

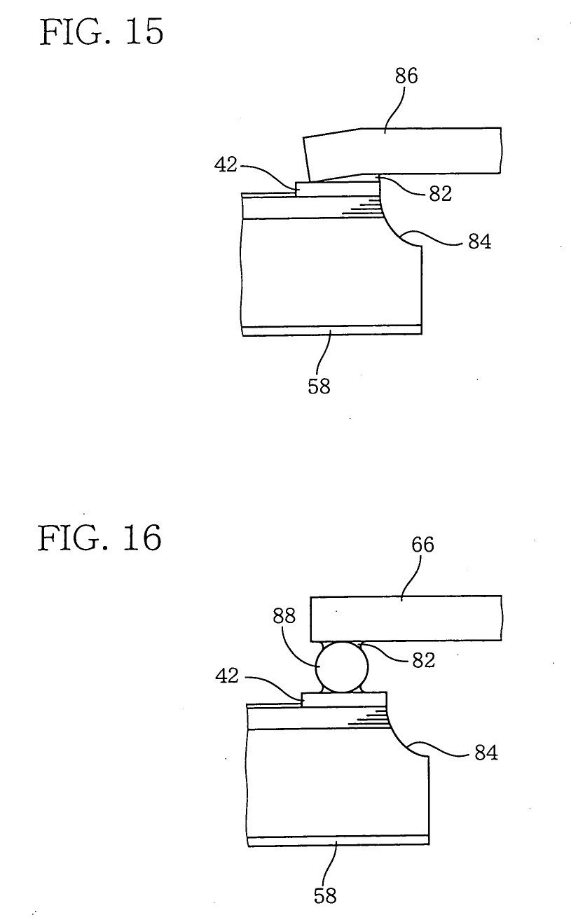

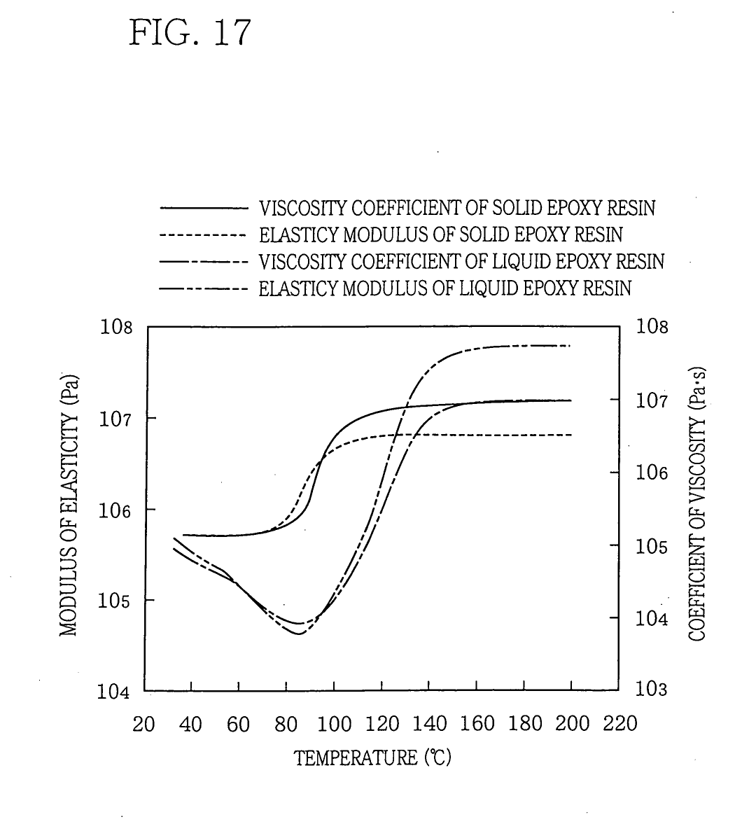

In the preceding embodiments of FIGS. 9-16, the straight metallic foils 66 are inclined at a suitable angle with respect to the upper surface of the upper electrodes 42. However, the straight metallic foils 66 may be replaced by bent metallic foils 86 each having a bent end portion at which the foil 86 is soldered to the upper electrode 42, as shown in FIG. 15. In this case, the end portion of the metallic foil 86 is inclined with respect to the upper surface of the upper electrode 42. Alternatively, the metallic foil 66 may be soldered to the upper electrode 42 via a metallic wire 88, as shown in FIG. 16. In these modifications, too, the solar cell 30 is protected from short-circuit of the electrically conductive member on the side of the light-receiving surface 40.

Although the photovoltaic electric generator of concentrator type in the embodiments of FIGS. 9-16 uses the solar cell 30 of multi-junction type, the principle of the present invention is equally applicable to a photovoltaic electric generator of concentrator type using a solar cell of a single-junction type.

In the solar cell assembly in the embodiments of FIGS. 9-16, the semiconductor structure of the solar cell 30 has the upper electrodes 42 formed on the upper surface and the lower electrode 58 formed on the lower surface, and the metallic foil 64 and the metallic foils 66 are soldered to those electrodes 42, 58. However, the upper electrodes 42 and the lower electrode 58 may be eliminated. In this case, the metallic foils 64, 66 are soldered directly to the lower and upper surfaces of the semiconductor structure.

While the heat dissipating layer 34 provided in the embodiments of FIGS. 9-16 consists of the two layers 34a, 34b, a single heat dissipating layer may be used, provided that the heat dissipating layer is formed of a thermoplastic material, a liquid epoxy resin or any other material the modulus of elasticity or coefficient of viscosity of which is lowered during a temperature rise of the material to a predetermined temperature in the process of heating of the material to its curing temperature.

It is to be understood that the present invention may be embodied with various other changes, modifications and improvements, which may occur to those skilled in the art, without departing from the spirit and scope of the invention defined in the appended claims.

What is claimed is:

1. A solar cell assembly comprising:
a solar cell having opposite surfaces one of which functions as a light-receiving surface;
a first lead electrode bonded to an end portion of said one of said opposite surfaces of said solar cell;
a second lead electrode bonded to a substantially entire portion of the other of said opposite surfaces; and
a metallic sheet which is bonded to one of opposite surfaces of said second lead electrode which is remote from said solar cell, said metallic sheet having a lower coefficient of thermal expansion than said second lead electrode.

2. The solar cell assembly according to claim 1, wherein said metallic sheet has a major surface area larger than a surface area of said opposite surfaces of said solar cell, and includes opposite end portions which extend from respective opposite ends of said solar cell in respective opposite directions in which said second lead electrode extends.

3. A photovoltaic electric generator of concentrator type comprising:
an array of a plurality of solar cell assemblies each including a solar cell, and electrically conductive members in the form of metallic foils connected to said solar cell;
a heat dissipating layer formed of a synthetic resin containing a thermally conductive filler; and
a base plate to which each of said solar cell assemblies is fixed through said heat dissipating layer,
and wherein said solar cell of said each solar cell assembly is embedded in said heat dissipating layer.

4. The photovoltaic electric generator of concentrator type according to claim 3, wherein said heat dissipating layer is formed of a material selected from a group consisting of: a thermoplastic material; and a non-thermoplastic material a modulus of elasticity or coefficient of viscosity of which is lowered to a minimal value during a rise of a temperature of the non-thermoplastic material within a predetermined range in the process of heating the material to cure the non-thermoplastic material.

5. The photovoltaic electric generator of concentrator type according to claim 3, wherein said solar cell has a light-receiving surface, and said electrically conductive members in the form of metallic foils extend outwardly from a periphery of said solar cell in a plane parallel to said light receiving surface.

6. The photovoltaic electric generator of concentrator type according to claim 3, wherein said solar cell has a light-receiving surface, and each of said plurality of solar cell assemblies further includes a sealing layer which is formed of a transparent resin and which covers said light-receiving surface.

7. The photovoltaic electric generator of concentrator type according to claim 6, wherein said sealing layer has a light-receiving surface, and each of said plurality of solar cell assemblies further includes a transparent glass plate which covers said light-receiving surface of said sealing layer.

8. The photovoltaic electric generator of concentrator type according to claim 3, wherein said solar cell has a light-receiving surface and at least one electrode formed on said light-receiving surface, and said electrically conductive members in the form of metallic foils include at least one foil which is soldered to said at least one electrode such that said at least one foil is inclined at a predetermined angle with respect to an upper surface of said at least one electrode.

9. A photovoltaic electric generator of concentrator type comprising:
an array of a plurality of solar cell assemblies each including a solar cell, and electrically conductive members in the form of metallic foils;
a heat dissipating layer formed of a synthetic resin containing a thermally conductive filler; and
a base plate to which each of said solar cell assemblies is fixed through said heat dissipating layer,
and wherein said heat dissipating layer consists of a first layer, and a second layer located on one of opposite sides of said first layer which is remote from said base plate, said second layer being formed of a material selected from a group consisting of: a thermoplastic material; and a non-thermoplastic material a modulus of elasticity or coefficient of viscosity of which is lowered below that of said first layer during a rise of a temperature of the non-thermoplastic material within a predetermined range in the process of heating of the material to cure the non-thermoplastic material.

10. The photovoltaic electric generator of concentrator type according to claim 9, wherein said first layer of said heat dissipating layer is formed of a thermosetting resin, and said non-thermoplastic material of said second layer is a thermosetting resin.

11. The photovoltaic electric generator of concentrator type according to claim 9, wherein said first layer of said heat dissipating layer is formed of a solid epoxy resin, while said second layer is formed of a liquid epoxy resin.

12. The photovoltaic electric generator of concentrator type according to claim 9, wherein said solar cell has a light-receiving surface, and said electrically conductive members in the form of metallic foils extend outwardly from a periphery of said solar cell in a plane parallel to said light receiving surface.

13. The photovoltaic electric generator of concentrator type according to claim 9, wherein said solar cell has a light-receiving surface, and each of said plurality of solar cell assemblies further includes a sealing layer which is formed of a transparent resin and which covers said light-receiving surface.

14. The photovoltaic electric generator of concentrator type according to claim 13, wherein said sealing layer has a light-receiving surface, and each of said plurality of solar cell assemblies further includes a transparent glass plate which covers said light-receiving surface of said sealing layer.

15. The photovoltaic electric generator of concentrator type according to claim 9, wherein said solar cell has a light-receiving surface and at least one electrode formed on said light-receiving surface, and said electrically conductive members in the form of metallic foils include at least one foil which is soldered to said at least one electrode such that said at least one foil is inclined at a predetermined angle with respect to an upper surface of said at least one electrode.

16. A photovoltaic electric generator of concentrator type comprising:
an array of a plurality of solar cell assemblies each including a solar cell, and electrically conductive members in the form of metallic foils;
a heat dissipating layer formed of a synthetic resin containing a thermally conductive filler; and
a base plate to which each of said solar cell assemblies is fixed through said heat dissipating layer,
and wherein sad metallic foils have a plurality of voids and are at least partially embedded in said heat dissipating layer such that said plurality of voids are filled with a material of said heat dissipating layer.

17. The photovoltaic electric generator of concentrator type according to claim 16, wherein said solar cell has a light-receiving surface, and said electrically conductive members in the form of metallic foils extend outwardly from a periphery of said solar cell in a plane parallel to said light receiving surface.

18. The photovoltaic electric generator of concentrator type according to claim 16, wherein said solar cell has a light-receiving surface, and each of said plurality of solar cell assemblies further includes a sealing layer which is formed of a transparent resin and which covers said light-receiving surface.

19. The photovoltaic electric generator of concentrator type according to claim 18, wherein said sealing layer has a light-receiving surface, and each of said plurality of solar cell assemblies further includes a transparent glass plate which covers said light-receiving surface of said sealing layer.

20. The photovoltaic electric generator of concentrator type according to claim 16, wherein said solar cell has a light-receiving surface and at least one electrode formed on said light-receiving surface, and said electrically conductive members in the form of metallic foils include at least one foil which is soldered to said at least one electrode such that said at least one foil is inclined at a predetermined angle with respect to an upper surface of said at least one electrode.
